(19) United States
(12) Patent Application Publication
(10) Pub. No.: US 2025/0309099 A1
(43) Pub. Date: Oct. 2, 2025

(54) DIRECTIONAL CONDUCTOR INTERCONNECT WITH EMBEDDED VIA

(71) Applicant: INTERNATIONAL BUSINESS MACHINES CORPORATION, Armonk, NY (US)

(72) Inventors: Takeshi Nogami, Schenectady, NY (US); Ching-Tzu Chen, Ossining, NY (US); Andrew Herbert Simon, Fishkill, NY (US); Kevin Wayne Brew, Niskayuna, NY (US); Martin Michael Frank, Dobbs Ferry, NY (US); Debarghya Sarkar, Latham, NY (US); Atharv Jog, Albany, NY (US); Son Nguyen, Schenectady, NY (US); Brock Mendoza, Mechanicville, NY (US)

(21) Appl. No.: 18/621,590

(22) Filed: Mar. 29, 2024

(51) Int. Cl. H01L 23/522; H01L 21/768; H01L 23/532

(52) U.S. Cl. CPC H01L 23/5226; H01L 21/76802; H01L 21/76879; H01L 23/53238; H01L 23/53276

(57) ABSTRACT

A semiconductor device includes a conductive line including an anisotropic material having crystal orientations of higher conductivity aligned parallel with a longitudinal direction of the conductive line. An embedded via is transversely oriented relative to the longitudinal direction. The embedded via is disposed within and in electrical contact with internal surfaces of the conductive line. A via is connected to the embedded via.

### BACKGROUND

The present invention generally relates to semiconductor devices and processing methods, and more particularly to conductive lines having directional conductive materials with an embedded via that improves connectivity.

Polynomial increase in line resistance with reduced pitch in conventional metal interconnects (e.g., Cu) is a major performance bottleneck in advanced semiconductor integrated circuits. Anisotropic conductors, including quasi-two dimensional (2D) conductors and quasi-one dimensional (1D) conductors, show high conductivity in the 2D plane direction or in the uniaxial direction. Topological conductors, including topological semimetals and topological metals, show resilient, high surface conduction. However, the cross-plane conductivity of these materials is much lower, rendering them unsuitable for many applications, as resistance between line conductors and connected vias is poor. Introducing the anisotropic and/or topological conductors gives rise to the problem of potential high contact resistance between a line and a via.

In addition, growing or placing anisotropic and topological conductors in a useful orientation for making good contact with the via is often challenging and does not solve the contact resistance problems between interconnect structures.

Therefore, a need exists for improved via-to-interconnect connections for the anisotropic and topological interconnect lines that can lower interface resistance between these structures.

### SUMMARY

In accordance with an embodiment of the present invention, a semiconductor device includes a conductive line including an anisotropic material having orientations of higher conductivity aligned parallel with a longitudinal direction of the conductive line. An embedded via is transversely oriented relative to the longitudinal direction. The embedded via is disposed within and in electrical contact with internal surfaces of the conductive line. A via is connected to the embedded via.

In other embodiments, the conductive line can include a depth and the embedded via is disposed within the depth. The conductive line can include an isotropic metal portion. The embedded via can have a larger footprint than the via. The conductive line cap includes a gap between lateral exterior walls of the conductive line and a dielectric material disposed about the conductive line. An additional via can contact a surface of the conductive line. The additional via can partially extend into the conductive line. The embedded via can extend beyond a surface of the conductive line.

In accordance with another embodiment of the present invention, a semiconductor device includes a first conductive line, a first via connected to conductive line and a second conductive line. The second conductive line includes an anisotropic material having orientations of higher conductivity aligned parallel with a longitudinal direction of the second conductive line. An embedded via is transversely oriented relative to the longitudinal direction. The embedded via is disposed within and in electrical contact with internal surfaces of the second conductive line and connected to the first via.

In other embodiments, the second conductive line can include a depth and the embedded via is disposed within the depth. The first conductive line can include an isotropic metal. The second conductive line can include an isotropic metal portion. The embedded via can have a larger footprint than the first via. The second conductive line can include a gap between lateral exterior walls of the second conductive line and a dielectric material disposed about the second conductive line. A second via contacts a surface of the second conductive line. The second via can partially extend into the second conductive line. The embedded via can extend beyond a surface of the second conductive line.

In accordance with another embodiment of the present invention, a semiconductor device includes a conductive line including a first portion having an anisotropic material with crystal orientations of higher conductivity aligned parallel with a longitudinal direction of the conductive line, and a second portion including an isotropic metal extending along the longitudinal direction. An embedded via is transversely oriented relative to the longitudinal direction. The embedded via is disposed within and in electrical contact with internal surfaces of the first portion of the conductive line. The embedded via is in electrical contact with the second portion of the conductive liner. A via is connected to the embedded via.

In other embodiments, the conductive line includes a depth and the embedded via can be disposed within the depth. The embedded via can have a larger footprint than the via.

These and other features and advantages will become apparent from the following detailed description of illustrative embodiments thereof, which is to be read in connection with the accompanying drawings.

### BRIEF DESCRIPTION OF THE DRAWINGS

The following description will provide details of preferred embodiments with reference to the following figures wherein:

FIG. 1 shows orthogonal cross-sectional views depicting dielectric layers having metal structures and a trench formed for a conductive line, in accordance with an embodiment of the present invention;

FIG. 2 shows orthogonal cross-sectional views showing dielectric layers having metal structures and a conductive line formed in the trench from anisotropic materials, in accordance with an embodiment of the present invention;

FIG. 3 shows orthogonal cross-sectional views showing an opening formed through the anisotropic material of the conductive line, in accordance with an embodiment of the present invention;

FIG. 4 shows orthogonal cross-sectional views showing the opening filled by an embedded via formed through the anisotropic material of the conductive line, in accordance with an embodiment of the present invention;

FIG. 5 shows orthogonal cross-sectional views showing dielectric layers having a conductive line formed with anisotropic material and an etch mask for forming a via, in accordance with an embodiment of the present invention;

FIG. 6 shows orthogonal cross-sectional views with a via hole opened up through one or more dielectric layers and through the conductive line formed with anisotropic material, in accordance with an embodiment of the present invention;

FIG. 7 shows orthogonal cross-sectional views with an embedded via that extends beyond a surface of the conductive line formed with anisotropic material, in accordance with an embodiment of the present invention;

FIG. 8 shows orthogonal cross-sectional views depicting dielectric layers having metal structures and a conductive line formed from a metal that isotropically conducts, in accordance with an embodiment of the present invention;

FIG. 9 shows orthogonal cross-sectional views depicting a trench for extending a conductive line with a conductive line extension, in accordance with an embodiment of the present invention;

FIG. 10 shows orthogonal cross-sectional views depicting a conductive line extension formed on the conductive line formed from a metal that isotopically conducts, the conductive line extension including anisotropic materials, in accordance with an embodiment of the present invention;

FIG. 11 shows orthogonal cross-sectional views depicting a dielectric cap layer over the conductive line extension for laser annealing, in accordance with an embodiment of the present invention;

FIG. 12 shows orthogonal cross-sectional views depicting an embedded via that extends beyond the conductive line extension and through the dielectric cap layer, in accordance with an embodiment of the present invention;

FIG. 13 shows orthogonal cross-sectional views depicting an embedded via that extends beyond the conductive line extension, through the dielectric cap layer and through another dielectric layer, in accordance with an embodiment of the present invention;

FIG. 14 shows orthogonal cross-sectional views depicting an embedded via within a conductive line made from anisotropic material, in accordance with an embodiment of the present invention;

FIG. 15 shows orthogonal cross-sectional views depicting the embedded via and an additional via that connects to the conductive line, in accordance with an embodiment of the present invention; and

FIG. 16 shows orthogonal cross-sectional views depicting the additional via connecting to another embedded via within the conductive line, in accordance with an embodiment of the present invention.

### DETAILED DESCRIPTION

In accordance with embodiments of the present invention, devices and methods are described which include incorporating directional conductors and/or topological conductors in conductive lines. For ease of reference, the directional conductors, including quasi-two-dimensional (2D), quasi-one-dimensional (1D) conductors, topological conductors, etc. will be referred to generally herein as anisotropic materials. Anisotropic materials can include, e.g., quasi-2D materials, such as, e.g., graphene, multilayered graphene, etc., among other materials that exhibit 2D high-conduction crystal planes, quasi-1D materials, such as, e.g., CoSn, carbon nanotubes, etc. among other materials that exhibit 1D high-conduction crystal axes, transition metal dichalcogenides (TMD), topological semimetals, topological metals, quasi-2D delafossites (e.g., PtCoO₂, PdCoO₂), MAX-phase layered nitrides and carbides and multilayers of the above materials.

Directional conductors can include quasi-1D conductors with high uniaxial conductivity, e.g., CoSn, carbon nanotubes, etc. Directional conductors can include quasi-2D conductors with high conductivity in two axes, e.g., multilayered graphene, etc. Topological conductors can include metals or semimetals wrapped around an insulating core. MAX phase materials are materials that are layered, hexagonal carbides and/or nitrides with the formula: Mₙ₊₁AXₙ, (MAX) where n=1 to 4, and M is an early transition metal, A is an A-group (e.g., IIIA and IVA, or groups 13 and 14) element and X is either C and/or N. Many anisotropic materials can provide a higher conductivity than Ru and even Cu, which are commonly employed materials for metallization structures in semiconductor processing.

In an embodiment, anisotropic material interconnect conductors are employed in conductive lines to improve the line resistance of the line conductors. A via can be embedded in a conductive line that includes anisotropic materials to improve the contact resistance and transport between the line conductor and via. Anisotropic materials can be formed on a conductive line or on another via or conductive structure. The anisotropic materials can be formed in a horizontal orientation (e.g., parallel to a plane of a substrate). The anisotropic materials, which exhibit a high in-plane conduction, are then etched to form a via hole or opening therein. An anisotropic etch, such as a reactive ion etch (RIE) provides a method for exposing underlying conductive materials below the anisotropic materials.

A metal conductor can be deposited within the via hole to form an embedded via disposed vertically in a cross-plane direction of the anisotropic materials. The via fill can include, e.g., an isotropic metal, such as, e.g., W, Cu, Ru, CuAl, CuAl₂, Co to form the embedded via, such that the highly conductive planes of a line conductor contact the via to achieve low contact resistance between the conductive line and the embedded via. The embedded via can vertically channel electric current flow along channels of the anisotropic materials. This results in low contact resistance between the embedded via and any metal conductors contacting the embedded via.

A dielectric layer can be formed over the embedded via and patterned to access the embedded via for connection to upper metal structures. The metal in the underlying conductive structure and metal in the embedded via can be the same or different. Combinations of metals can also be employed to reduce both the metal/metal resistance and the (in-plane) (line resistance).

In other embodiments, the anisotropic materials can be employed as a conductive line and include one or more embedded vias. The embedded via lowers the contact resistance between the line conductor including anisotropic materials and a via connected to the embedded via within the line conductor. In another embodiment, a conductive line can include a metal with an anisotropic material layer formed thereon having one or more embedded vias. The anisotropic materials can be directly contacted by additional vias or other conductive structures.

Methods for forming anisotropic in-plane line conductors include exposing an underlying metal structure, e.g., a top of a metal via or line conductor, by etching a dielectric layer. An etched region of the dielectric layer is then filled with a metal (e.g., CuAl₂) to form a via on top of exposed metal via (or conductive line). After a chemical mechanical polish (CMP) of the metal of the via, another dielectric layer is formed and patterned for a conductive line. The conductive line is formed by employing anisotropic materials which are formed in contact with the via. The anisotropic materials include planes of current flow which are horizontal. A patterned etch opens up a hole in the anisotropic materials down to the via. An embedded via is deposited and planarized to a surface of the anisotropic material of the line conductor.

In another embodiment, an anisotropic material line conductor is formed in a dielectric layer. One or more dielectric layers are formed over the line conductor. A via hole is opened up through the one or more dielectric layers and continues into or through the anisotropic materials of the conductive line. A via is formed through the dielectric layers and is embedded within the anisotropic materials of the conductive line. Additional connections can be made to the embedded via.

In another embodiment, an anisotropic material is deposited selectively on a metal conductive line. The anisotropic material can aid in improving conduction through the conductive line. In another embodiment, an embedded via can be formed through the anisotropic material to contact the metal line conductor.

In some embodiments, via metal is extended into the conductive line or interconnect which includes anisotropic materials. The conductive line can include multilayers of anisotropic conductors with high in-plane conductivity where electrons can flow directly to the via that extends into the conductive line. Anisotropic conductors can include quasi-1D, quasi-2D materials (e.g., graphene, TMD, PtCoO₂, PdCoO₂), thin films of topological conductors, quasi-2D/metal multilayers, topological conductor/metal multilayers, topological/quasi-2D multilayers, etc. The present embodiments can be applied to a broad class of interconnects with high in-plane and low cross-plane conductivity.

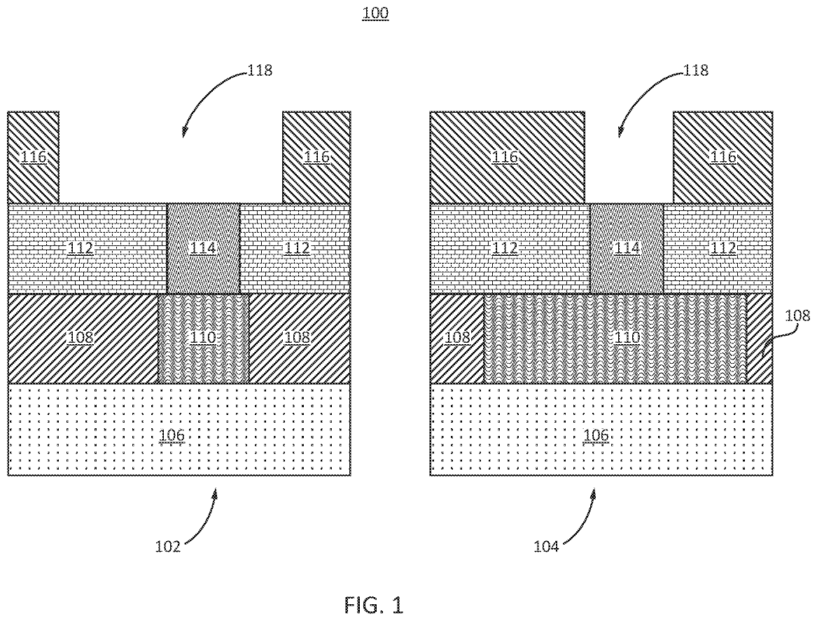

Referring now to the drawings in which like numerals represent the same or similar elements and initially to FIG. 1, devices and methods for manufacturing interconnect structures with embedded vias are shown in accordance with embodiments of the present invention.

A wafer 100 includes underlying layers 106 having multiple layers on which interconnects with embedded vias will be fabricated. FIG. 1 depicts views 102 and 104. Views 102 and 104 are cross-sections of the wafer 100 that are taken orthogonally to one another.

The underlying layers 106 can include any suitable substrate structure, e.g., a bulk semiconductor, a semiconductor-on-insulator (SOI) substrate, etc., and preferably includes a monocrystalline semiconductor. In one example, the substrate can include a silicon-containing material. Illustrative examples of Si-containing materials suitable for the substrate can include, but are not limited to, Si, SiGe, SiGeC, SiC and multi-layers thereof. Although silicon is the predominantly used semiconductor material in wafer fabrication, alternative semiconductor materials can be employed as additional layers, such as, but not limited to, germanium, gallium arsenide, gallium nitride, silicon germanium, cadmium telluride, zinc selenide, etc.

The underlying layers 106 can include any number of layers including metal structures, electronic components (e.g., transistors, etc.) and any other structures employed in semiconductor devices.

A dielectric layer 108 is formed on the underlying layers 106 and can include any suitable material, e.g., selected from the group consisting of silicon containing materials such as SiO₂, Si₃N₄, SiOₓN_{y}, SiC, SiCO, SiCOH, SiCNO, and SiCH compounds, the above-mentioned silicon containing materials with some or all of the Si replaced by Ge, carbon doped oxides, inorganic oxides, inorganic polymers, hybrid polymers, organic polymers such as polyamides or SiLK™, other carbon containing materials, organo-inorganic materials such as spin-on glasses and silsesquioxane-based materials, and diamond-like carbon (DLC), also known as amorphous hydrogenated carbon, α-C: H). The dielectric layer 108 can be deposited using chemical vapor deposition (CVD), although other deposition methods can be employed.

The dielectric layer 108 is patterned to form trenches for the formation of a conductive line 110. Conductive line 110 is formed by depositing a conductive fill to fill in the trenches in dielectric layer 108. The conductive fill is planarized by a chemical mechanical polish (CMP). The conductive fill that forms the conductive line 110 can include isotropic metal materials, such as, e.g., Cu, Ru, Mo, Rh, W, Ir, Co, CuMn, and alloys or combinations of these and other conductive materials. In a particularly useful embodiment, the conductive fill includes Cu, CuAl or CuAl₂. The conductive fill can be formed using a deposition method, such as, e.g., CVD, plasma enhanced CVD (PECVD), atomic layer deposition (ALD), electroplating or any other suitable deposition method.

In some embodiments, a diffusion barrier (not shown) can be formed prior to the conductive fill. The diffusion barrier can include, e.g., TiN, TaN, Ta, TMD, or similar materials.

Another dielectric layer 112 can be formed over the dielectric layer 108. The dielectric layer 112 can be formed in a similar manner as dielectric layer 108. Dielectric layer 112 can include a same material or a different material than dielectric layer 108. Dielectric layer 112 can include SiO₂, Si₃N₄, SiOₓN_{y}, SiC, SiCO, SiCOH, SiCNO, and SiCH compounds, silicon containing materials with some or all of the Si replaced by Ge, carbon doped oxides, inorganic oxides, inorganic polymers, hybrid polymers, organic polymers such as polyamides or SiLK™, other carbon containing materials, organo-inorganic materials such as spin-on glasses and silsesquioxane-based materials, and diamond-like carbon (DLC), also known as amorphous hydrogenated carbon, α-C: H).

The dielectric layer 112 is patterned to form trenches for the formation of vias 114. Via 114 is formed by depositing a conductive fill to fill in the trenches in dielectric layer 112. The conductive fill is planarized by a CMP. The conductive fill that forms the via 114 can include isotropic metal materials, such as, e.g., Cu, Ru, Mo, Rh, W, Ir, Co, CuMn and alloys or combinations of these and other conductive materials. In a particularly useful embodiment, the conductive fill includes Cu, CuAl or CuAl₂. The conductive fill can be formed using a deposition method, such as, e.g., CVD, PECVD, ALD or any other suitable deposition method.

In some embodiments, a diffusion barrier (not shown) can be formed prior to the conductive fill. The diffusion barrier can include, e.g., TiN, TaN, Ta, TMD, or similar materials. Via 114 connects to the conductive line 110.

A dielectric layer 116 can be formed over the dielectric layer 112. The dielectric layer 116 can be formed in a similar manner as dielectric layers 108 and 112. Dielectric layer 116 can include a same material or a different material than dielectric layers 108 and 112. Dielectric layer 116 can include SiO₂, Si₃N₄, SiOₓN_{y}, SiC, SiCO, SiCOH, SiCNO, and SiCH compounds, silicon containing materials with some or all of the Si replaced by Ge, carbon doped oxides, inorganic oxides, inorganic polymers, hybrid polymers, organic polymers such as polyamides or SiLK™, other carbon containing materials, organo-inorganic materials such as spin-on glasses and silsesquioxane-based materials, and diamond-like carbon (DLC), also known as amorphous hydrogenated carbon, α-C: H). The dielectric layer 116 is patterned to form trench 118 for the formation of conductive lines.

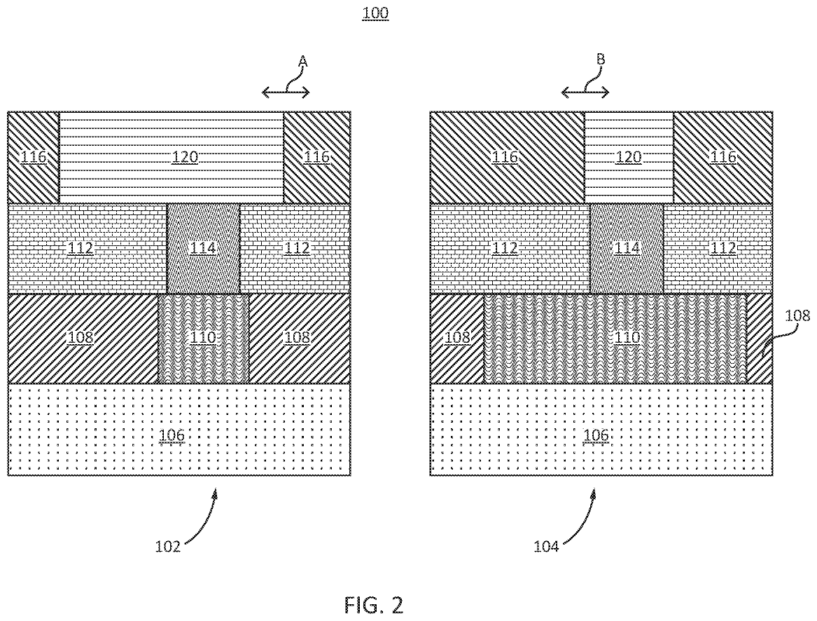

Referring to FIG. 2, the conductive line 120 is formed by forming an anisotropic material in the trench 118. The anisotropic material can include, e.g., quasi-1D materials, graphene, multilayered graphene, transition metal dichalcogenides (TMD), topological semimetals, topological metals, quasi-2D delafossites (e.g., PtCoO₂, PdCoO₂), MAX-phase layered nitrides and carbides, among other materials that exhibit high-conductivity crystal planes, and multilayers of the above materials. The anisotropic material is aligned to permit good conduction horizontally, e.g., predominantly in the direction of arrow “A” for quasi-1D materials and in the direction of arrows “A” and “B” (“A” and “B” being orthogonal relative to one another) for quasi-2D materials and others. Quasi-1D materials include a one-dimensional anisotropic conduction path arranged with high-conductivity crystalline axes parallel to a longitudinal direction of the conductive line 120. Quasi-2D materials include a two-dimensional anisotropic conduction path arranged with high-conductivity crystalline planes parallel to a longitudinal direction of the conductive line 120. Topological structures are similar to quasi-2D materials with conductive paths at bottoms of trenches and along sidewalls parallel to a longitudinal direction of the conductive line 120.

Depending on the type of material used, the conductive line 120 can be formed layer by layer to achieve crystal planes for horizontal conduction. In one example, graphene or multilayered graphene can be formed by depositing material, e.g., by CVD a using selective growth process.

In other embodiments, a templating layer can be formed in trench 118 to assist the crystallographic growth of the anisotropic material. In still other embodiments, a crystal seed layer can be deposited followed by a deposition process to provide crystal growth of anisotropic materials. In other embodiments, self-assembled monolayers (SAM) and molecular nanolayers can be employed to assist is forming the anisotropic material and structures for conductive line 120.

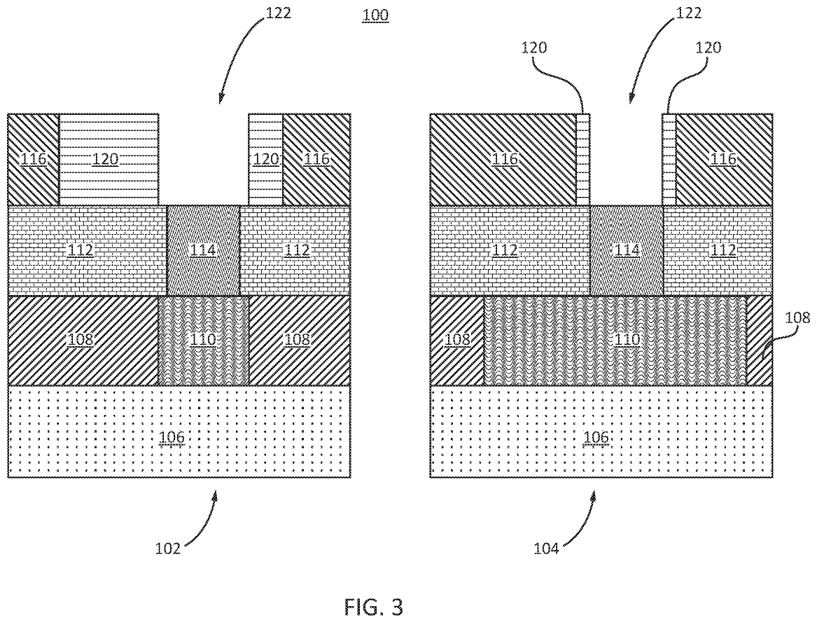

Referring to FIG. 3, trenches 122, which can include or holes, can be patterned using photolithographic patterning techniques to create an etch mask to etch the trenches 122 with an anisotropic etch., e.g., RIE. The trenches 122 are etched into the anisotropic material of the conductive line 120. The trenches 122 expose the underlying via 114. The trenches 122 pass transversely to the high conductive planes or axis of the anisotropic material of conductive line 120.

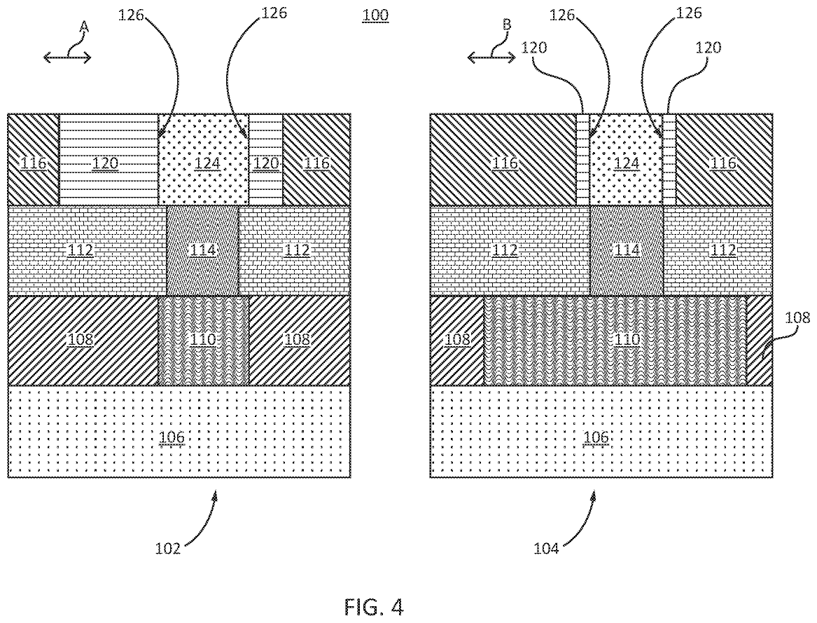

Referring to FIG. 4, an embedded via 124 is formed by depositing a conductive fill to fill in the trenches or holes in dielectric layer 116. In an embodiment, the embedded via 124 is formed within a depth of the conductive line 120. The conductive fill is planarized by a CMP. The conductive fill that forms the embedded via 124 can include isotropic metal materials, such as, e.g., Cu, Ru, Mo, Rh, W, Ir, Co, CuMn, and alloys or combinations of these and other conductive materials. In a particularly useful embodiment, the conductive fill includes Cu, CuAl or CuAl₂. The conductive fill can be formed using a deposition method, such as, e.g., CVD, PECVD, ALD or any other suitable deposition method.

The embedded via 124 extends the via 114 into the anisotropic materials of the conductive line 120. The embedded via 124 forms a highly conductive interface 126 with electric current flow traveling in the direction of “A” and/or “B”. In this way, the embedded via 124 channels electric current flow from the horizontal axis or planes toward the via 114. This can significantly reduce line and contact resistance. Processing can continue with the formation of additional metal structures that can include vias, conductive lines and other components. These structures can include one or more additional conductive structures (e.g., vias and conductive line or interconnects) in different layers. The one or more additional conductive structures can include anisotropic materials.

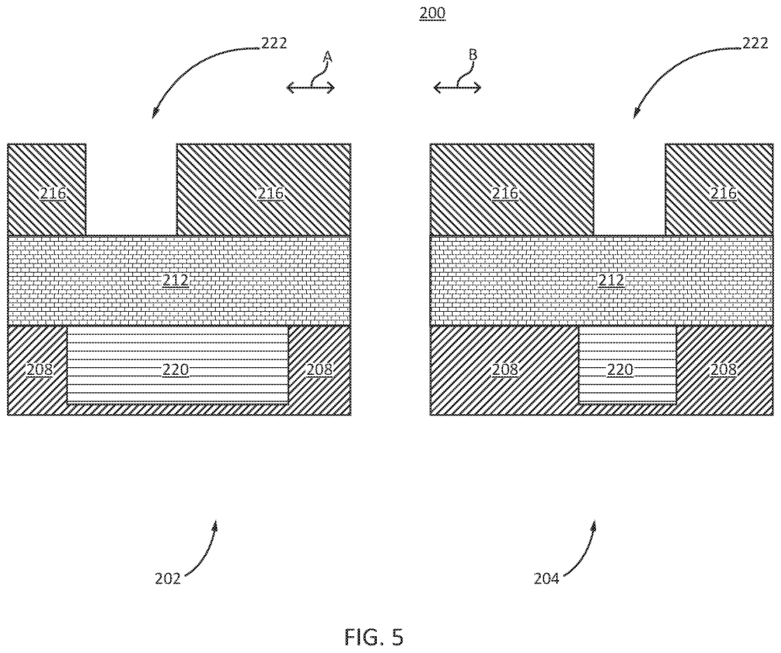

Referring to FIG. 5, a wafer 200 can include underlying layers (not shown) similar to underlying layers 106 having multiple layers on which interconnects with embedded vias will be fabricated. FIG. 5 depicts views 202 and 204. Views 202 and 204 are cross-sections of the wafer 200 that are taken orthogonally to one another.

A dielectric layer 208 can be formed on a substrate or other layer and can include any suitable material, e.g., selected from the group consisting of silicon containing materials such as SiO₂, Si₃N₄, SiOₓN_{y}, SiC, SiCO, SiCOH, SiCNO, and SiCH compounds, the above-mentioned silicon containing materials with some or all of the Si replaced by Ge, carbon doped oxides, inorganic oxides, inorganic polymers, hybrid polymers, organic polymers such as polyamides or SiLK™, other carbon containing materials, organo-inorganic materials such as spin-on glasses and silsesquioxane-based materials, and diamond-like carbon (DLC), also known as amorphous hydrogenated carbon, α-C: H). The dielectric layer 208 can be deposited using CVD, although other deposition methods can be employed.

The dielectric layer 208 is patterned to form trenches for the formation of a conductive line 220. Conductive line 220 is formed by forming an anisotropic material in the trench. The anisotropic material can include, e.g., quasi-1D material, quasi-2D material, topological semimetal thin films and multilayers, MAX-phase layered nitrides and carbides, among other materials that exhibit high-conduction crystal axes and planes. The anisotropic material is aligned to permit good conduction horizontally, e.g., predominantly in directions of arrows “A” and “B” (“A” and “B” being orthogonal relative to one another). For quasi-1D materials, the anisotropic material is aligned in the direction of arrow “A”.

Depending on the type of material used for the anisotropic materials, the conductive line 120 can be formed layer by layer to achieve crystal planes with horizontal conduction. In one example, graphene or multilayered graphene can be formed by depositing material, e.g., by CVD a using selective growth process.

In other embodiments, a templating layer can be formed in trench to assist the crystallographic growth of the anisotropic material. In still other embodiments, a crystal seed layer can be deposited followed by a deposition process to provide crystal growth of anisotropic materials. In other embodiments, self-assembled monolayers (SAM) or molecular nanolayers can be employed to assist is forming the anisotropic material for conductive line 220.

Another dielectric layer 212 can be formed over the dielectric layer 208 and the conductive line 220. The dielectric layer 212 can be formed in a similar manner to dielectric layer 208. Dielectric layer 212 can include a same material or a different material than dielectric layer 208.

A mask layer 216 is deposited on the dielectric layer 212. The mask layer can include a photoresist or other mask material Trenches 222 can be patterned using photolithographic patterning techniques to create an etch mask.

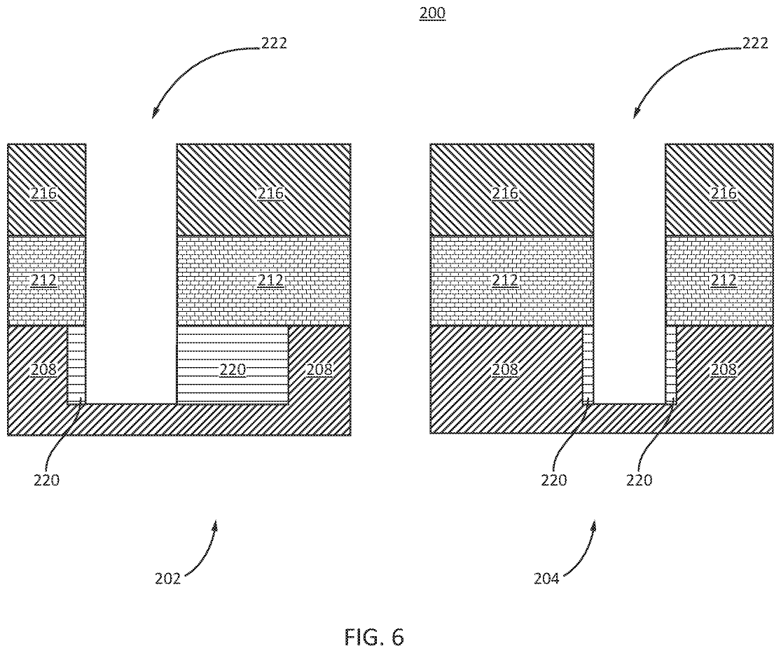

Referring to FIG. 6, the mask layer 216 is employed to etch through the dielectric layer 212 and through the anisotropic materials of the conductive line 220 by extending trenches 222 using an etch process. The etch can stop at any depth within the conductive line 220 or can etch completely through the conductive line 220.

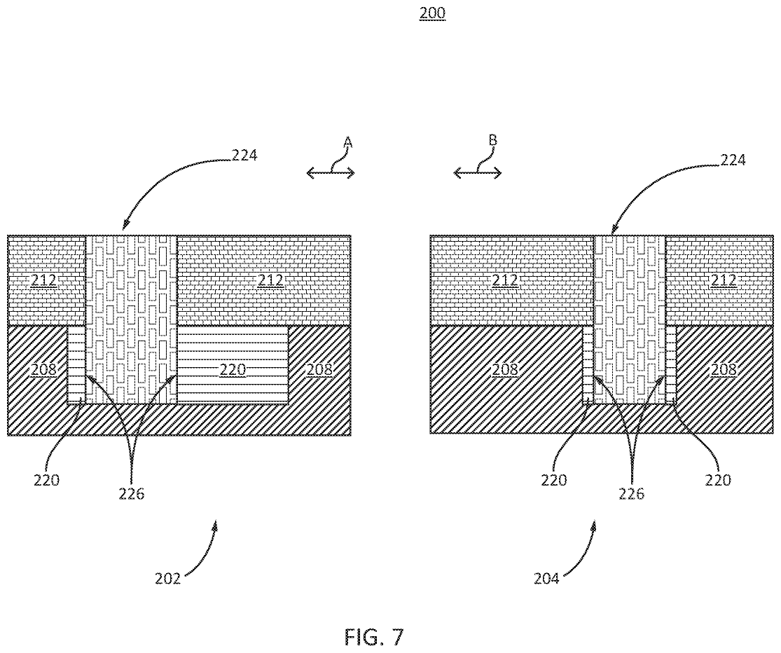

Referring to FIG. 7, the mask layer 216 can be removed. A conductive fill fills in the trenches 222 in dielectric layer 212. The conductive fill is planarized by CMP. The conductive fill forms an embedded via 224. The embedded via can include isotropic metal materials, such as, e.g., Cu, Ru, Mo, Rh, W, Ir, Co, CuMn, and alloys or combinations of these and other conductive materials. In a particularly useful embodiment, the conductive fill includes Cu, CuAl or CuAl₂. The conductive fill can be formed using a deposition method, such as, e.g., CVD, PECVD, ALD or any other suitable deposition method.

The embedded via 224 extends through one or more dielectric layers and into the anisotropic materials of the conductive line 220. The embedded via 224 forms a highly conductive interface 226 with electric current flow traveling in the directions of “A” and/or “B”. In this way, the embedded via 224 channels electric current flow from the 2D horizontal planes toward the via 224. This can significantly reduce line and contact resistance. Processing can continue with the formation of additional metal structures that can include vias, conductive lines and other components. These structures can include one or more additional conductive structures (e.g., vias and conductive line or interconnects) in different layers. The one or more additional conductive structures can include anisotropic materials.

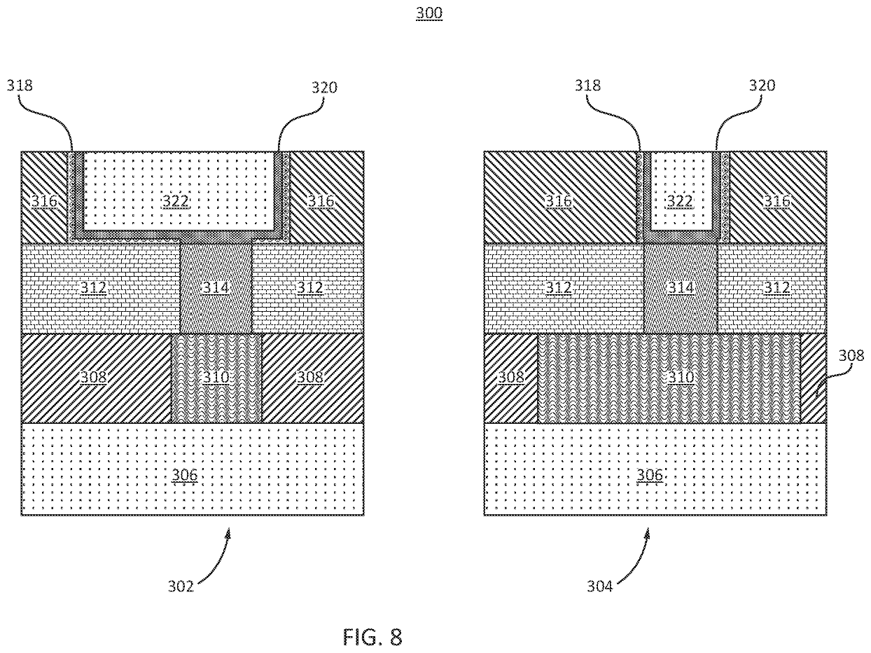

Referring to FIG. 8, a wafer 300 includes underlying layers 306 having multiple layers on which interconnects with embedded vias will be fabricated. The underlying layers 306 can include any number of layers including metal structures, electronic components (e.g., transistors, etc.) and any other structures employed in semiconductor devices. FIG. 8 depicts views 302 and 304. Views 302 and 304 are cross-sections of the wafer 300 that are taken orthogonally to one another.

A dielectric layer 308 is formed on the underlying layer 306 and can include any suitable material. The dielectric layer 308 can be deposited using CVD, although other deposition methods can be employed.

The dielectric layer 308 is patterned to form trenches for the formation of a conductive line 310. Conductive line 310 is formed by depositing a conductive fill to fill in the trenches in dielectric layer 308. The conductive fill is planarized by CMP. The conductive fill that forms the conductive line 310 can include isotropic metal materials, such as, e.g., Cu, Ru, Mo, Rh, W, Ir, Co, CuMn, and alloys or combinations of these and other conductive materials. In a particularly useful embodiment, the conductive fill includes Cu, CuAl, or CuAl₂. The conductive fill can be formed using a deposition method, such as, e.g., CVD, PECVD, ALD or any other suitable deposition method.

In some embodiments, a diffusion barrier (not shown) can be formed prior to the conductive fill. The diffusion barrier can include, e.g., TiN, TaN, Ta, TMD, or similar materials.

Another dielectric layer 312 can be formed over the dielectric layer 308. The dielectric layer 312 can be formed in a similar manner to dielectric layer 308. The dielectric layer 312 can include a same material or a different material than dielectric layer 308. The dielectric layer 312 is patterned to form trenches for the formation of vias 314. Via 314 is formed by depositing a conductive fill to fill in the trenches in dielectric layer 312. The conductive fill is planarized by CMP. The conductive fill that forms the via 314 can include isotropic metal materials, such as, e.g., Cu, Ru, Mo, Rh, W, Ir, Co, CuMn, and alloys or combinations of these and other conductive materials. In a particularly useful embodiment, the conductive fill includes Cu, CuAl or CuAl₂. The conductive fill can be formed using a deposition method, such as, e.g., CVD, PECVD, ALD or any other suitable deposition method.

In some embodiments, a diffusion barrier can be formed prior to the conductive fill. The diffusion barrier can include, e.g., TiN, TaN, Ta, TMD, or similar materials. Via 314 connects to the conductive line 310.

A dielectric layer 316 can be formed over the dielectric layer 312. The dielectric layer 316 can be formed in a similar manner as dielectric layers 308 and 312. The dielectric layer 316 can include a same material or a different material than dielectric layers 308 and 312. The dielectric layer 316 is patterned to form trenches for the formation of conductive lines 322.

Prior to forming the conductive lines 322, deposition of one or more layers can be performed within the trench. In an embodiment, a first liner 318 and a second liner 320 can be conformally deposited within the trench for the conductive line 322. The first liner 318 can include a diffusion barrier, e.g., TiN, TaN, Ta, TMD, or similar materials. The second liner 320 can include an adhesion or transitional layer (e.g., Co) to support formation of the metal for the conductive line 322. Other types of liners or layers can also be employed instead of or in addition to the first liner 318 and the second liner 320.

The conductive line 322 is formed by depositing a conductive fill to fill in the trenches in dielectric layer 316. The conductive fill is planarized by CMP. The conductive fill that forms the conductive line 322 can include isotropic metal materials, such as, e.g., Cu, Ru, Mo, Rh, W, Ir, Co, CuAl, CuAl₂, CuMn and alloys or combinations of these and other conductive materials. In a particularly useful embodiment, the conductive fill includes Cu, CuAl, or CuAl₂. The conductive fill can be formed using a deposition method, such as, e.g., CVD, PECVD, ALD, electroplating or any other suitable deposition method.

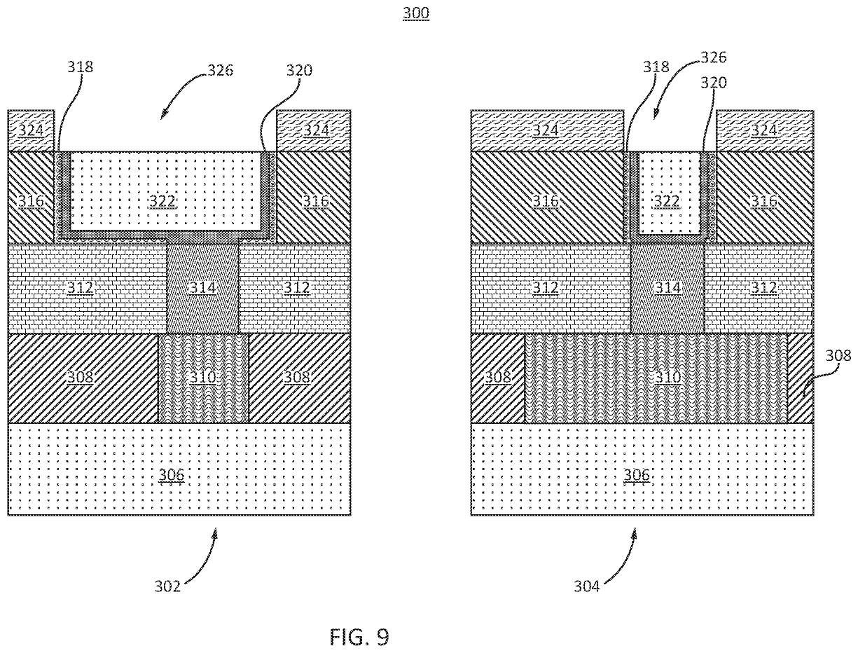

Referring to FIG. 9, a dielectric layer 324 is formed over the dielectric layer 316 and the conductive line 322. The dielectric layer 324 can be formed using a selective deposition process (e.g., ALD, CVD or other deposition methods). In another embodiment, the dielectric layer 324 can be selectively etched relative to the dielectric layer 316, the conductive line 322, the first liner 318 and the second liner 320. A photoresist or other mask layer (not shown) can be employed to pattern a trench 326 using photolithographic patterning techniques. The trench 326 exposes the conductive line 322, the first liner 318 and the second liner 320. The dielectric layer 324 can include, e.g., an oxide, a nitride, although other suitable materials can be employed. The etch process can include a wet etch in accordance with an etch mask (not shown).

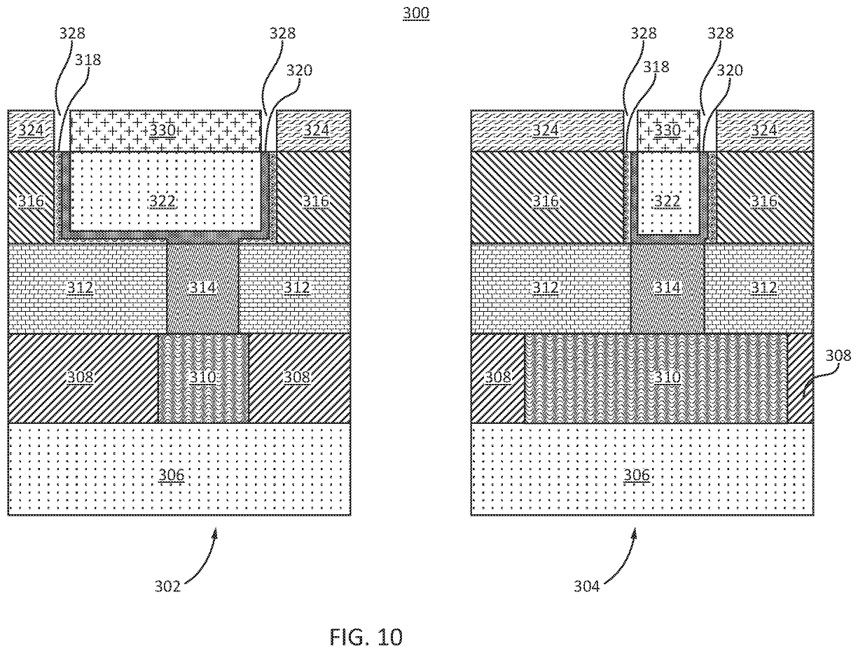

In another embodiment, a trench can be formed within the conductive line 322 after formation by recessing of the conductive line 322 and performing a deposition of an additional conductor, which can include an anisotropic conductor to form a compound conductive line including two or more materials (e.g., anisotropic materials) or layers of a same material with the same or different properties. In an embodiment, selective deposition as described with respect to FIG. 10 can begin within the recess.

Referring to FIG. 10, exposed portions of the conductive line 322 are employed as a surface for selective deposition of an anisotropic material (e.g., multilayered graphene). Selective deposition includes growing the anisotropic material on the surface of the isotropic metal of conductive line 322. Selective deposition can be performed, e.g., using ALD, CVD or other processes. The selective deposition results in a conductive line extension 330 being formed in contact with the conductive line 322. Since the deposition is selective, the deposition is tuned to grow on the conductive line 322 and not on the first liner 318 and the second liner 320. This results in a gap or spacing 328 between dielectric layer 324 and the conductive line extension 330.

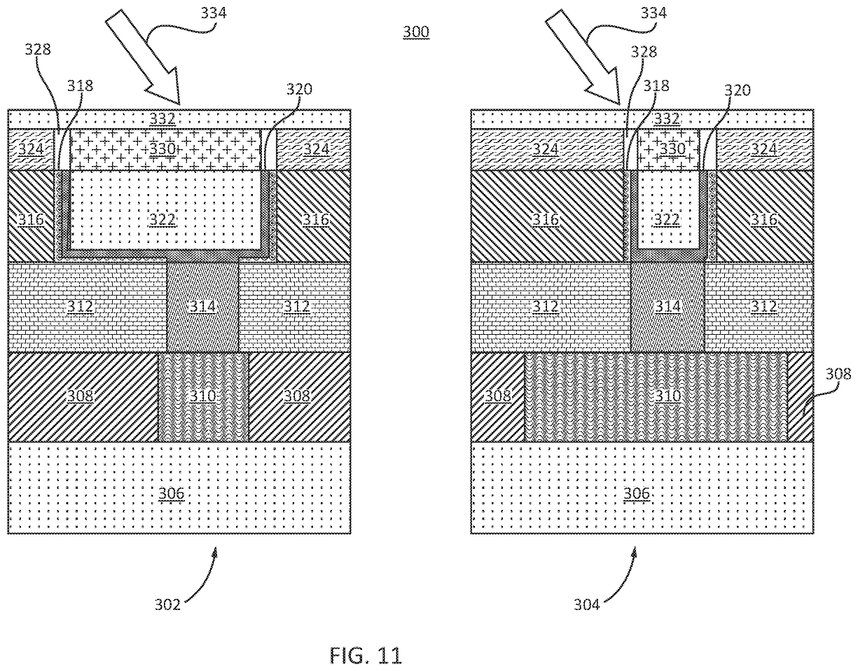

Referring to FIG. 11, a dielectric cap layer 332 is formed over the dielectric layer 324 and the conductive line extension 330. The dielectric cap layer 332 can be formed using a deposition process (e.g., ALD, CVD or other deposition methods). The dielectric cap layer 332 can include, e.g., SiCN, although other suitable materials can be employed.

A laser anneal can be performed. A laser beam 334 can be directed at the anisotropic material of the conductive line extension 330 below the dielectric cap layer 332. The laser anneal densifies the anisotropic material to enhance the crystallographic form of the anisotropic material.

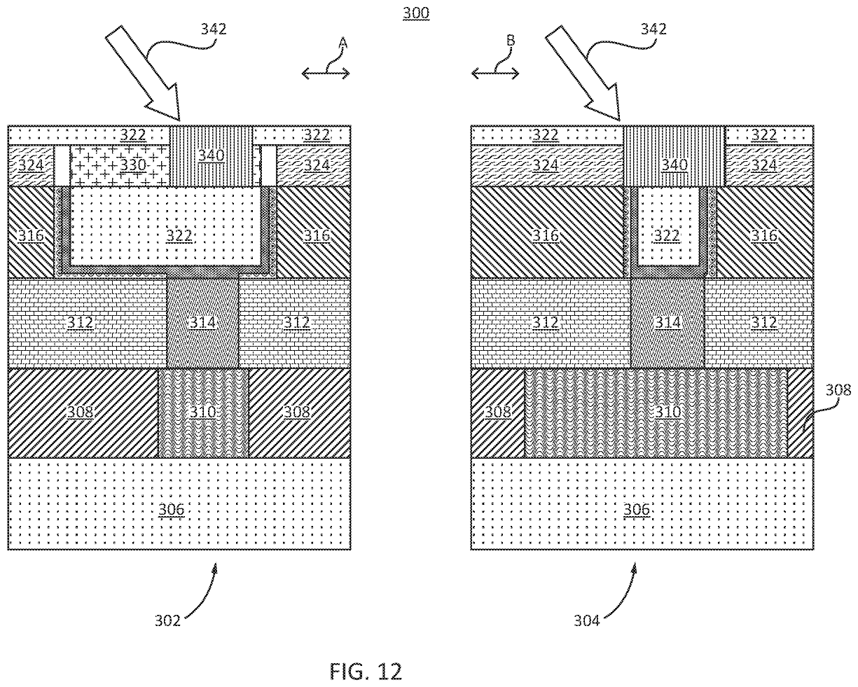

Referring to FIG. 12, an etch mask can be formed and an etch process performed to open up the dielectric cap layer 332 and further etch the anisotropic material of the conductive line extension 330. The etch can include a RIE. The etch exposes the conductive line 322.

An embedded via 340 is formed by depositing a conductive fill to fill in the trench formed by the etch through the dielectric cap layer 332 and the conductive line extension 330. The conductive fill is planarized by CMP. The conductive fill that forms the embedded via 340 can include isotropic metal materials, such as, e.g., Cu, Ru, Mo, Rh, W, Ir, Co, CuMn, and alloys or combinations of these and other conductive materials. In a particularly useful embodiment, the conductive fill includes Cu, CuAl or CuAl₂. The conductive fill can be formed using a deposition method, such as, e.g., CVD, PECVD, ALD or any other suitable deposition method. The embedded via 340 extends into the anisotropic materials of the conductive line extension 330.

Another laser anneal can be performed. A laser beam 342 can be directed at the anisotropic material of the conductive line extension 330 below the dielectric cap layer 332. The laser anneal densifies the anisotropic material to enhance the crystallographic form of the anisotropic material.

The embedded via 340 forms a highly conductive interface with the conductive line extension 330. Electric current flow travels in the directions of “A” and/or “B” (direction “A” for quasi-1D materials). In this way, electric current flow along the conductive line 322 can find additional electrical paths through the conductive line extension 330. The electric charge flow from the isotropic material of the conductive line 322 and the horizontal planes or axis of the conductive line extension 330 is channeled into the embedded via 340. This can significantly reduce line and contact resistance. Processing can continue with the formation of additional metal structures that can include vias, conductive lines and other components. These structures can include one or more additional conductive structures (e.g., vias and conductive line or interconnects) in different layers. The one or more additional conductive structures can include anisotropic materials.

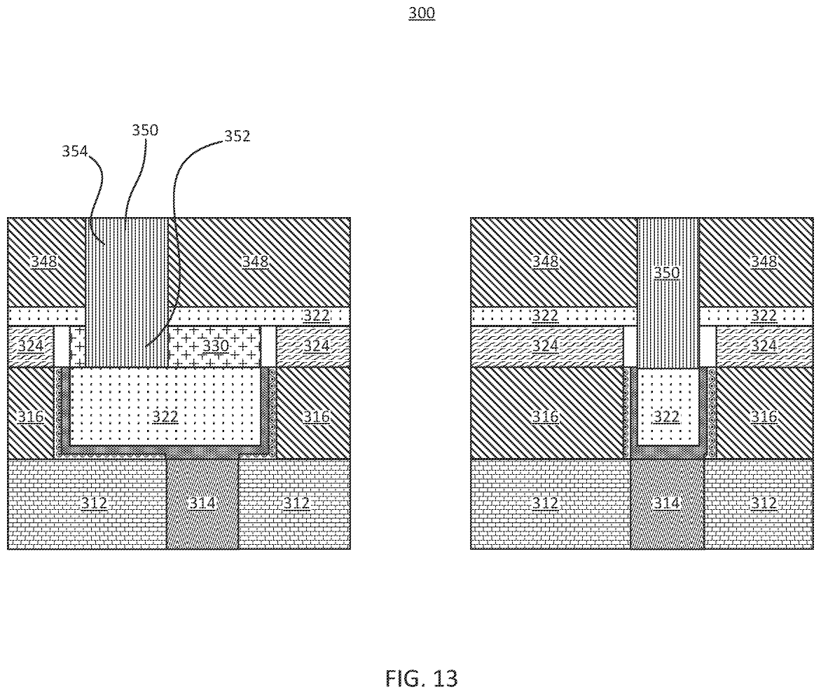

Referring to FIG. 13, in another embodiment, an extended via 350 can be formed. One or more additional dielectric layers 348 can be formed and patterned to form via holes. The via holes can extend through the anisotropic material of the conductive line extension 330. The etch can include a RIE. The etch exposes the conductive line 322.

The extended via 350 includes an embedded portion 352, which is formed by depositing a conductive fill to fill in the via hole through multiple levels of material to contact the conductive line 322 through the conductive line extension 330. The conductive fill is planarized by CMP. The conductive fill that forms the extended via 350 can include isotropic metal materials, such as, e.g., Cu, Ru, Mo, Rh, W, Ir, and alloys or combinations of these and other conductive materials. In a particularly useful embodiment, the conductive fill includes Cu, CuAl or CuAl₂. The conductive fill can be formed using a deposition method, such as, e.g., CVD, PECVD, ALD or any other suitable deposition method. The extended via 350 can extend through more than one level (e.g., multiple dielectric layers) of the device and connect with the conductive line 322 through the anisotropic materials of the conductive line extension 330.

The extended via 350 forms a highly conductive interface with the conductive line extension 330. In this way, electric current flow along the conductive line 322 can find additional electrical paths through the conductive line extension 330. This electric charge flow from the isotropic material of the conductive line 322 and the horizontal planes or axis of the conductive line extension 330 are channeled into the extended via 350. This can significantly reduce contact resistance between the extended via 350 and the conductive line 322. Processing can continue with the formation of additional metal structures that can include vias, conductive lines and other components. These structures can include one or more additional anisotropic conductive structures (e.g., vias and conductive line or interconnects) in different layers. The one or more additional anisotropic conductive structures can include anisotropic materials.

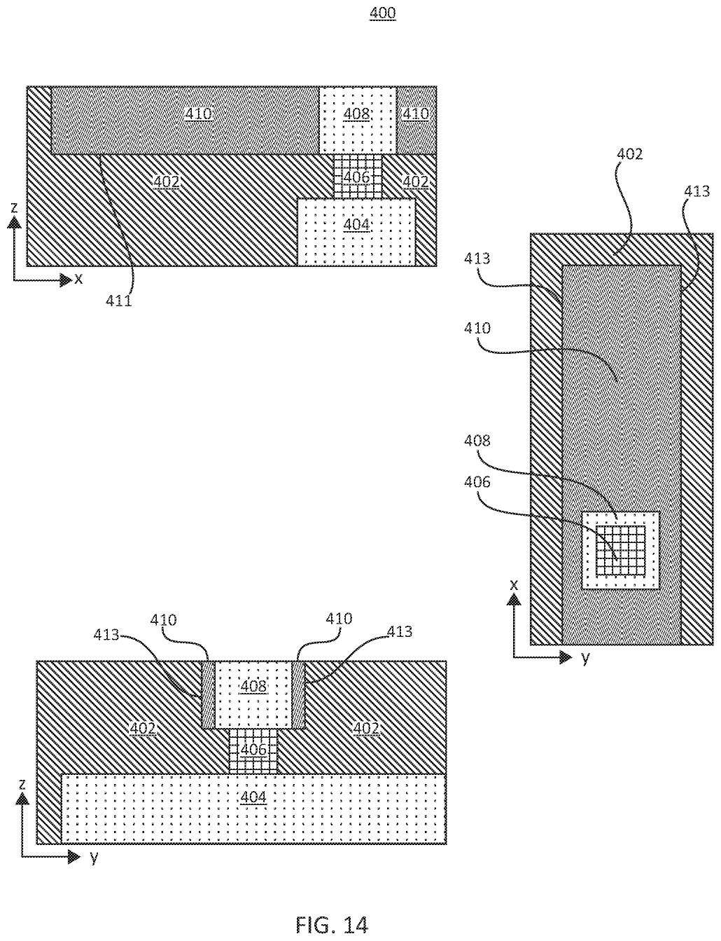

Referring to FIG. 14, a device 400 is shown in three orthogonal view cross-sections. The cross-sections are taken through a plane zx, a plane zy and a plane xy, as indicated in FIG. 14. A metal line or conductive line 404 is connected to a via 406. An extended via or embedded via 408 connects to the via 406. The embedded via 408 is embedded with an anisotropic material of a conductive line 410. The conductive line 410 includes an anisotropic conduction path with high conduction along the xy plane. In another embodiment, the conductive line 410 can have an anisotropic conduction path with high conduction along the xy plane near a trench bottom 411 and along the xz plane near the sidewalls 413 of the trench in which the conductive line 410 is formed (e.g., in a topological structure). Conduction in the z direction at the interface between the conductive line 410 and the via 406 is greatly improved by the presence of the conductive line 410 with highly conductive anisotropic materials and embedded via 408.

The via 406, embedded via 408 and conductive line 410 can be formed in different processes. The via 406 and embedded via 408 can include a same or different isotropic conductors, e.g., Cu, CuAl, CuAl₂, etc. The conductive line 410 can include anisotropic conductors and topological conductors. In an embodiment, embedded via 408 can include additional size when compared to via 406. The additional size increases conductive surface area with the anisotropic materials of the conductive line 410 to reduce line and contact resistance for the conductive line 410 and between the conductive line 410 and the via 406 and ensures that the embedded via 408 contacts the entire exposed surface of via 406.

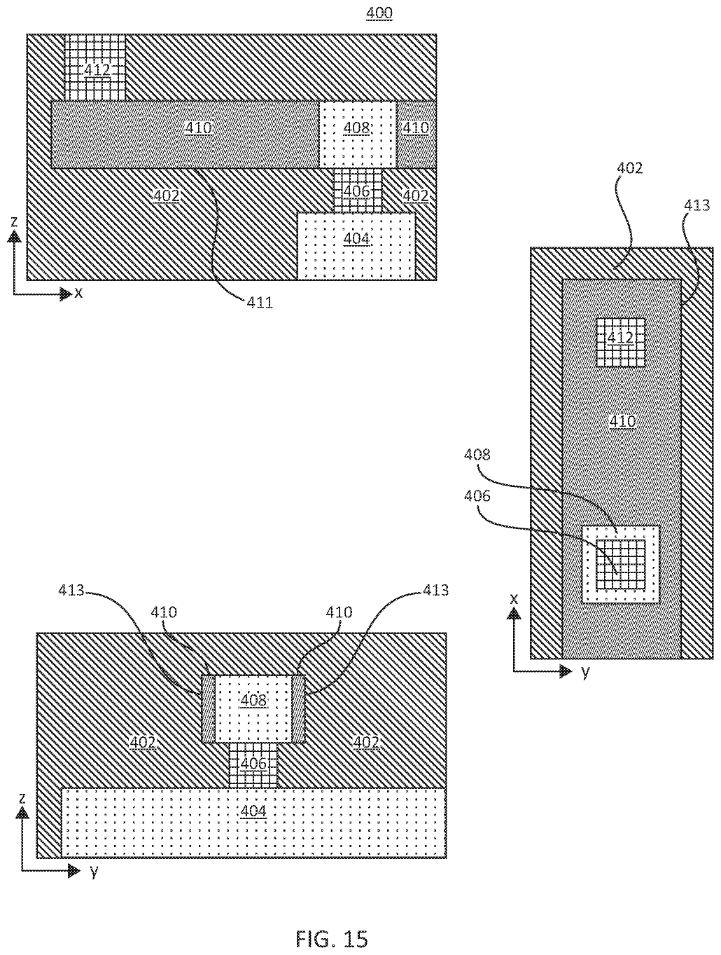

Referring to FIG. 15, device 400 can include a via 412 that contacts the conductive line 410 without being embedded in the conductive line 410. The via 412 can interface with a surface of the conductive line 410 or can be partially inset into the surface of the conductive line 410. The via 412 can connect to additional metal structures above the via 412. The conductive line 410 includes an anisotropic conduction path with high conduction along the xy plane. In another embodiment, the conductive line 410 can have an anisotropic conduction path with high conduction along the xy plane near a trench bottom 411 and along the xz plane near the sidewalls 413 of the trench in which the conductive line 410 is formed. Conduction in the z direction at the interface between the conductive line 410 and the via 412 is likely reduced but overall conduction can be improved if the via 412 is at least partially sunk into the conductive line 410 to take advantage of the highly conductive anisotropic materials. The via 412 can be formed from an isotropic conductor, e.g., Cu, CuAl, CuAl₂, etc.

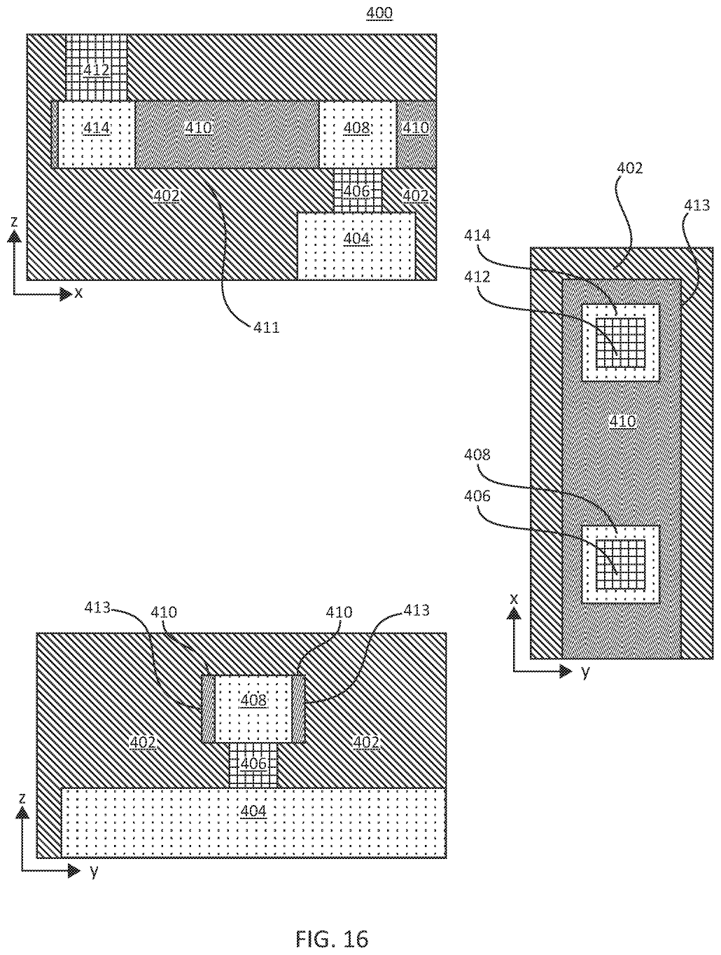

Referring to FIG. 16, device 400 can include an additional embedded via 414 that is embedded with the conductive line 410 and connects with via 412. The embedded via 414 is embedded within the anisotropic material of the conductive line 410. The conductive line 410 includes an anisotropic conduction path with high conduction along the xy plane. In another embodiment, the conductive line 410 can have an anisotropic conduction path with high conduction along the xy plane near a trench bottom 411 and along the xz plane near the sidewalls 413 of the trench in which the conductive line 410 is formed.

In an embodiment, embedded via 414 can include additional size when compared to via 412. The additional size increases conductive surface area with the 2D materials of the conductive line 410 to reduce contact resistance between the conductive line 410 and the via 412 and ensures that the embedded via 408 contacts the entire exposed surface of via 406.

Exemplary applications/uses to which the present invention can be applied include, but are not limited to semiconductor devices. Semiconductor devices can include processors, memory devices, application specific integrated circuits (ASICs), logic circuits or devices, combinations of these and any other circuit device. In such devices, one or more semiconductor devices can be included in a central processing unit, a graphics processing unit, and/or a separate processor- or computing element-based controller (e.g., logic gates, etc.). The semiconductor devices can include one or more on-board memories (e.g., caches, dedicated memory arrays, read only memory, etc.). In some embodiments, the semiconductor devices can include one or more memories that can be on or off board or that can be dedicated for use by a hardware processor subsystem (e.g., ROM, RAM, basic input/output system (BIOS), etc.).

In some embodiments, the semiconductor devices can include and execute one or more software elements. The one or more software elements can include an operating system and/or one or more applications and/or specific code to achieve a specified result. In still other embodiments, the semiconductor devices can include dedicated, specialized circuitry that perform one or more electronic processing functions to achieve a specified result. Such circuitry can include one or more field programmable gate arrays (FPGAs), and/or programmable applications programmable logic arrays (PLAs).

It is to be understood that aspects of the present invention will be described in terms of a given illustrative architecture; however, other architectures, structures, substrate materials and process features and steps can be varied within the scope of aspects of the present invention.

It will also be understood that when an element such as a layer, region or substrate is referred to as being “on” or “over” another element, it can be directly on the other element or intervening elements can also be present. In contrast, when an element is referred to as being “directly on” or “directly over” another element, there are no intervening elements present. It will also be understood that when an element is referred to as being “connected” or “coupled” to another element, it can be directly connected or coupled to the other element or intervening elements can be present. In contrast, when an element is referred to as being “directly connected” or “directly coupled” to another element, there are no intervening elements present.

The present embodiments can include a design for an integrated circuit chip, which can be created in a graphical computer programming language, and stored in a computer storage medium (such as a disk, tape, physical hard drive, or virtual hard drive such as in a storage access network). If the designer does not fabricate chips or the photolithographic masks used to fabricate chips, the designer can transmit the resulting design by physical means (e.g., by providing a copy of the storage medium storing the design) or electronically (e.g., through the Internet) to such entities, directly or indirectly. The stored design is then converted into the appropriate format (e.g., GDSII) for the fabrication of photolithographic masks, which typically include multiple copies of the chip design in question that are to be formed on a wafer. The photolithographic masks are utilized to define areas of the wafer (and/or the layers thereon) to be etched or otherwise processed.

Methods as described herein can be used in the fabrication of integrated circuit chips. The resulting integrated circuit chips can be distributed by the fabricator in raw wafer form (that is, as a single wafer that has multiple unpackaged chips), as a bare die, or in a packaged form. In the latter case, the chip is mounted in a single chip package (such as a plastic carrier, with leads that are affixed to a motherboard or other higher level carrier) or in a multichip package (such as a ceramic carrier that has either or both surface interconnections or buried interconnections). In any case, the chip is then integrated with other chips, discrete circuit elements, and/or other signal processing devices as part of either (a) an intermediate product, such as a motherboard, or (b) an end product. The end product can be any product that includes integrated circuit chips, ranging from toys and other low-end applications to advanced computer products having a display, a keyboard or other input device, and a central processor.

It should also be understood that material compounds will be described in terms of listed elements, e.g., SiGe. These compounds include different proportions of the elements within the compound, e.g., SiGe includes SiₓGe₁₋ₓ where x is less than or equal to 1, etc. In addition, other elements can be included in the compound and still function in accordance with the present principles. The compounds with additional elements will be referred to herein as alloys.

Reference in the specification to “one embodiment” or “an embodiment”, as well as other variations thereof, means that a particular feature, structure, characteristic, and so forth described in connection with the embodiment is included in at least one embodiment. Thus, the appearances of the phrase “in one embodiment” or “in an embodiment”, as well any other variations, appearing in various places throughout the specification are not necessarily all referring to the same embodiment.

It is to be appreciated that the use of any of the following “/”, “and/or”, and “at least one of”, for example, in the cases of “A/B”, “A and/or B” and “at least one of A and B”, is intended to encompass the selection of the first listed option (A) only, or the selection of the second listed option (B) only, or the selection of both options (A and B). As a further example, in the cases of “A, B, and/or C” and “at least one of A, B, and C”, such phrasing is intended to encompass the selection of the first listed option (A) only, or the selection of the second listed option (B) only, or the selection of the third listed option (C) only, or the selection of the first and the second listed options (A and B) only, or the selection of the first and third listed options (A and C) only, or the selection of the second and third listed options (B and C) only, or the selection of all three options (A and B and C). This can be extended, as readily apparent by one of ordinary skill in this and related arts, for as many items listed.

The terminology used herein is for the purpose of describing particular embodiments only and is not intended to be limiting of example embodiments. As used herein, the singular forms “a,” “an” and “the” are intended to include the plural forms as well, unless the context clearly indicates otherwise. It will be further understood that the terms “comprises,” “comprising,” “includes” and/or “including,” when used herein, specify the presence of stated features, integers, steps, operations, elements and/or components, but do not preclude the presence or addition of one or more other features, integers, steps, operations, elements, components and/or groups thereof.

Spatially relative terms, such as “beneath,” “below,” “lower,” “above,” “upper,” “top,” “bottom” and the like, can be used herein for ease of description to describe one element's or feature's relationship to another element(s) or feature(s) as illustrated in the FIGS. It will be understood that the spatially relative terms are intended to encompass different orientations of the device in use or operation in addition to the orientation depicted in the FIGS. For example, if the device in the FIGS. is turned over, elements described as “below” or “beneath” other elements or features would then be oriented “above” the other elements or features. Thus, the term “below” can encompass both an orientation of above and below. The device can be otherwise oriented (rotated 90 degrees or at other orientations), and the spatially relative descriptors used herein can be interpreted accordingly. In addition, it will also be understood that when a layer is referred to as being “between” two layers, it can be the only layer between the two layers, or one or more intervening layers can also be present.

It will be understood that, although the terms first, second, etc. can be used herein to describe various elements, these elements should not be limited by these terms. These terms are only used to distinguish one element from another element. Thus, a first element discussed below could be termed a second element without departing from the scope of the present concept.

Having described preferred embodiments of devices and methods (which are intended to be illustrative and not limiting), it is noted that modifications and variations can be made by persons skilled in the art in light of the above teachings. It is therefore to be understood that changes may be made in the particular embodiments disclosed which are within the scope of the invention as outlined by the appended claims. Having thus described aspects of the invention, with the details and particularity required by the patent laws, what is claimed and desired protected by Letters Patent is set forth in the appended claims.

1. A semiconductor device, comprising:
a conductive line including an anisotropic material having orientations of higher conductivity aligned parallel with a longitudinal direction of the conductive line;
an embedded via transversely oriented relative to the longitudinal direction, the embedded via disposed within and in electrical contact with internal surfaces of the conductive line; and
a via connected to the embedded via.

2. The semiconductor device as recited in claim 1, wherein the conductive line includes a depth and the embedded via is disposed within the depth.

3. The semiconductor device as recited in claim 1, wherein the conductive line includes an isotropic metal portion.

4. The semiconductor device as recited in claim 1, wherein the embedded via has a larger footprint than the via.

5. The semiconductor device as recited in claim 1, wherein the conductive line includes a gap between lateral exterior walls of the conductive line and a dielectric material disposed about the conductive line.

6. The semiconductor device as recited in claim 1, further comprising an additional via contacting a surface of the conductive line.

7. The semiconductor device as recited in claim 6, wherein the additional via partially extends into the conductive line.

8. The semiconductor device as recited in claim 1, wherein the embedded via extends beyond a surface of the conductive line.

9. A semiconductor device, comprising:
a first conductive line;
a first via connected to conductive line;
a second conductive line including an anisotropic material having orientations of higher conductivity aligned parallel with a longitudinal direction of the second conductive line; and
an embedded via transversely oriented relative to the longitudinal direction, the embedded via disposed within and in electrical contact with internal surfaces of the second conductive line and connected to the first via.

10. The semiconductor device as recited in claim 9, wherein the second conductive line includes a depth and the embedded via is disposed within the depth.

11. The semiconductor device as recited in claim 9, wherein the first conductive line includes an isotropic metal.

12. The semiconductor device as recited in claim 9, wherein the second conductive line includes an isotropic metal portion.

13. The semiconductor device as recited in claim 9, wherein the embedded via has a larger footprint than the first via.

14. The semiconductor device as recited in claim 9, wherein the second conductive line includes a gap between lateral exterior walls of the second conductive line and a dielectric material disposed about the second conductive line.

15. The semiconductor device as recited in claim 9, further comprising a second via contacting a surface of the second conductive line.

16. The semiconductor device as recited in claim 15, wherein the second via partially extends into the second conductive line.

17. The semiconductor device as recited in claim 9, wherein the embedded via extends beyond a surface of the second conductive line.

18. A semiconductor device, comprising:
a conductive line including a first portion having an anisotropic material with crystal orientations of higher conductivity aligned parallel with a longitudinal direction of the conductive line, and a second portion including an isotropic metal extending along the longitudinal direction;
an embedded via transversely oriented relative to the longitudinal direction, the embedded via disposed within and in electrical contact with internal surfaces of the first portion of the conductive line, the embedded via in electrical contact with the second portion of the conductive liner; and
a via connected to the embedded via.

19. The semiconductor device as recited in claim 18, wherein the conductive line includes a depth and the embedded via is disposed within the depth.

20. The semiconductor device as recited in claim 18, wherein the embedded via has a larger footprint than the via.
